(19) United States
(12) Patent Application Publication
(10) Pub. No.: US 2021/0364835 A1
(43) Pub. Date: Nov. 25, 2021

(54) CONDUCTIVE LAYER INSULATION METHOD, CONDUTIVE LAYER INSULATION STRUCTURE, AND DISPLAY DEVICE

(71) Applicant: HKC CORPORATION LIMITED, Shenzhen (CN)

(72) Inventor: Beizhou HUANG, Shenzhen (CN)

(21) Appl. No.: 17/042,447

(22) PCT Filed: Nov. 29, 2018
(86) PCT No.: PCT/CN2018/118294

§ 371 Date: Sep. 28, 2020

(30) Foreign Application Priority Data
Oct. 8, 2018 (CN) 201811168685.5

(51) Int. Cl. G02F 1/1368; G02F 1/1362; H01L 29/786; H01L 29/66

(52) U.S. Cl. CPC G02F 1/1368; G02F 1/136286; G02F 1/136277; H01L 29/66742; H01L 29/7869

(57) ABSTRACT

Embodiments of the present disclosure provide a conductive layer insulation method, a conductive layer insulation structure, and a display device. The method includes: forming a conductive layer over a substrate, the conductive layer including data lines and sources of switching elements; forming a first insulation layer to cover the conductive layer; and forming a second insulation layer to cover the first insulation layer, a side surface of the second insulation layer away from the first insulation layer being connected to a color resist layer; where a density of the first insulation layer is greater than a density of the second insulation layer.

### CROSS REFERENCE TO RELATED APPLICATIONS

The present disclosure claims the benefit of Chinese Patent Application No. 2018111686855, filed on Oct. 8, 2018, entitled “CONDUCTIVE LAYER INSULATION METHOD, CONDUCTIVE LAYER INSULATION STRUCTURE, AND DISPLAY DEVICE”, the entire content of which is incorporated herein in its entirety.

### TECHNICAL FIELD

The present disclosure relates to the field of liquid crystal display technologies, and more particularly relates to a conductive layer insulation method, a conductive layer insulation structure, and a display device.

### BACKGROUND

The thin film transistor-liquid crystal display (TFT-LCD) has the advantages of high image quality, light weight, low power consumption, no radiation, etc., and has gradually become the mainstream of display devices. With the development of thin film transistor-liquid crystal displays in terms of super large size, high driving frequency, high resolution, etc., the quality requirements of the wire manufacture procedure technology for the thin film transistor liquid-crystal displays are becoming higher and higher.

In order to meet the development requirements of high-frequency high-resolution liquid crystal display specifications in the future, aluminum alloy or pure aluminum metal wires are usually replaced with copper metal with lower resistance as a wire material. Since copper ions have higher activity and are easily oxidized, a problem that copper ions diffuse will occur. For example, on a COA type (color filter on array substrate, CF on Array) liquid crystal panel, copper metal is used as a wire material, which easily causes diffused copper ions to contaminate the color resist in a color filter film, resulting in electric leakage and direct current (DC) residues, producing afterimages.

### SUMMARY

In view of this, the present disclosure provides a conductive layer insulation method, a conductive layer insulation structure, and a display device which prevent ion diffusion.

In one aspect, an embodiment of the present disclosure provides a conductive layer insulation method, which is applied to a display panel. The display panel includes at least a substrate, a plurality of switching elements, a plurality of data lines, and a plurality of scanning lines. A color resist layer is disposed on the substrate, and the switching element includes at least a source. The method includes:

forming a conductive layer over the substrate, the conductive layer including the data line and the source of the switching element;

forming a first insulation layer to cover the conductive layer; and

forming a second insulation layer to cover the first insulation layer, a surface of the second insulation layer away from the first insulation layer being connected to the color resist layer,

a density of the first insulation layer is greater than a density of the second insulation layer.

In another aspect, an embodiment of the present disclosure provides a conductive layer insulation structure, which is applied to a display panel. The display panel includes at least a substrate, a plurality of switching elements, a plurality of data lines, and a plurality of scanning lines. A color resist layer is disposed on the substrate, and the switching element includes at least a source. The conductive layer insulation structure includes:

a conductive layer, formed over the substrate, the conductive layer including the data line and the source of the switching element;

a first insulation layer, covering the conductive layer; and

a second insulation layer, covering the first insulation layer, a side surface of the second insulation layer away from the first insulation layer being connected to the color resist layer,

a density of the first insulation layer is greater than a density of the second insulation layer.

In still another aspect, an embodiment of the present disclosure provides a display device. The display device includes a housing and a display panel. The display panel includes:

a substrate;

a pixel unit;

a switching element;

a conductive layer insulation structure; and

a plurality of data lines and a plurality of scanning lines,

a color resist layer is disposed on the substrate; the pixel unit and the switching element are disposed in areas surrounded by the plurality of data lines and the plurality of scanning lines orthogonally intersected;

the conductive layer insulation structure includes: a first insulation layer, covering the conductive layer; and

a second insulation layer, covering the first insulation layer, a surface of the second insulation layer away from the first insulation layer being connected to the color resist layer;

a density of the first insulation layer is greater than a density of the second insulation layer.

The embodiments of the present disclosure provide a conductive layer insulation method, a conductive layer insulation structure, and a display device. The method includes: forming the conductive layer over the substrate, the conductive layer including the data line and the source of the switching element; forming a first insulation layer to cover the conductive layer; and forming a second insulation layer to cover the first insulation layer, a side surface of the second insulation layer away from the first insulation layer being connected to a color resist layer; where the density of the first insulation layer is greater than the density of the second insulation layer. By implementing the embodiments of the present disclosure, the metal ions in the conductive layer can be effectively prevented from diffusing outwardly.

### BRIEF DESCRIPTION OF THE DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a flowchart of a conductive layer insulation method in an embodiment of the present disclosure;

FIG. 2 is a schematic view of a conductive layer insulation structure in an embodiment of the present disclosure;

FIG. 3 is a schematic view of a conductive layer insulation structure in an embodiment of the present disclosure; and

FIG. 4 is a schematic view of a display device in an embodiment of the present disclosure.

### DETAILED DESCRIPTION OF THE EMBODIMENTS

To make the objectives, technical solutions, and advantages of the present disclosure clearer and more comprehensible, the following further describes the present disclosure in detail with reference to the accompanying drawings and embodiments. It should be understood that the specific embodiments described herein are merely used to explain the present disclosure but are not intended to limit the present disclosure.

It should be understood that the terms “include”, “comprise”, and/or variants thereof, when used in this specification and the appended claims, specify the presence of stated features, integers, steps, operations, elements, and/or components, but do not preclude the presence or addition of one or more other features, integers, steps, operations, elements, components, and/or groups thereof.

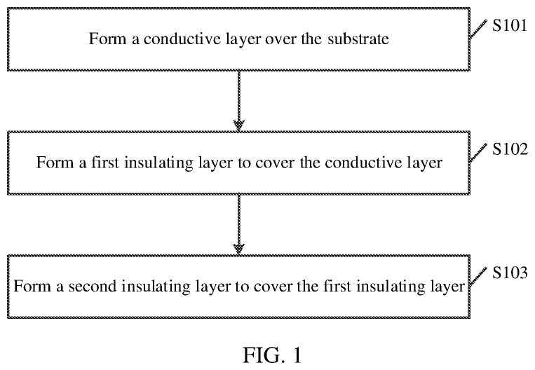

Referring to FIG. 1, which is a flowchart of a conductive layer insulation method in an embodiment of the present disclosure. The display panel includes a substrate, a plurality of switching elements, a plurality of data lines, and a plurality of scanning lines. The switching element includes at least a source, and a color resist layer is disposed on the substrate. The method includes steps S101 to S103.

In S101: a conductive layer is formed over the substrate, the conductive layer includes the data line and the source of the switching element.

In a specific implementation, the display panel includes an array substrate, where the array substrate includes the substrate, a plurality of switching elements, a plurality of data lines, and a plurality of scanning lines, and the substrate may be formed by a substrate such as a glass substrate, a plastic substrate or the like. The array substrate can be applied to display panels of various display devices. For example, the display panel may be a liquid crystal display panel in a thin film transistor-liquid crystal display (TFT-LCD). Specifically, the array substrate may be a thin film transistor array substrate. The switching element may be a thin film transistor. The switching element includes a source, a gate, a drain, an active layer, etc.

The data lines and the sources of the switching elements are electrically coupled and formed on the substrate to cooperatively serve as the conductive layer.

In a specific implementation, the conductive layer may be a copper metal conductive layer or a copper alloy conductive layer. If the conductive layer is a copper metal conductive layer, the formation of the conductive layer can be achieved by depositing a metal copper film on the substrate by sputtering using a pure copper target. The copper film is patterned into the conductive layer by processes such as exposure, development, etching, etc.

If the array substrate is a thin film transistor array substrate, the conductive layer includes data lines disposed on the substrate, and sources of switching elements disposed in the substrate. The data lines and the sources of the switching elements are electrically coupled. In particular, scanning lines for being connected to the gates may further be formed between the conductive layer and the substrate. A gate insulation layer may be formed between the conductive layer and the scanning lines, the gate insulation layer completely covers the scanning lines, and the gate insulation layer is used for insulating and separating the conductive layer from the scanning lines.

In S102: a first insulation layer is formed to cover the conductive layer.

In a specific implementation, the method of forming the first insulation layer may include, but not limited to, direct-current vacuum magnetron sputtering, radio-frequency vacuum magnetron sputtering and reactive sputtering.

The material of the first insulation layer may be silicon nitride or silicon oxide. The thickness of the first insulation layer may be 100 angstroms to 300 angstroms, for example, the thickness of the first insulation layer may be 100 angstroms, 200 angstroms, 300 angstroms, or the like.

In S103: a second insulation layer is formed to cover the first insulation layer, and a side surface of the second insulation layer away from the first insulation layer is connected to the color resist layer.

In a specific implementation, the method of forming the second insulation layer includes, but not limited to, direct-current vacuum magnetron sputtering, radio-frequency vacuum magnetron sputtering and reactive sputtering. A forming speed of the first insulation layer is less than a forming speed of the second insulation layer. A density of the first insulation layer is greater than a density of the second insulation layer. The second insulation layer may be silicon nitride or silicon oxide.

A surface of the second insulation layer away from the first insulation layer is connected to the color resist layer, and the surface connected to the color resist layer may be the upper or side surface of the second insulation layer. The color resist layer includes a plurality of color resist blocks disposed in the same layer, and the color resist blocks include a red color resist, a green color resist, and a blue color resist. The color resist blocks in the color resist layer may be arranged in an array. For example, the color resist blocks of each row are alternately arranged in the order of the red color resist block, the green color resist block, and the blue color resist block.

Specifically, the density of the first insulation layer is greater than the density of the second insulation layer. The forming speed of the first insulation layer is less than the forming speed of the second insulation layer. The material of first insulation layer may be silicon oxide.

Specifically, a ratio of the thickness of the first insulation layer to the thickness of the second insulation layer is 1:10. For example, the thickness of the first insulation layer may be 150 angstroms; and correspondingly, the thickness of the second insulation layer may be 1500 angstroms. Alternatively, the thickness of the first insulation layer may be 200 angstroms; and correspondingly, the thickness of the second insulation layer may be 2000 angstroms. Alternatively, the thickness of the first insulation layer may be 250 angstroms; and correspondingly, the thickness of the second insulation layer may be 2500 angstroms.

The above layers may also be formed by other manners, such as chemical vapor deposition, physical deposition or the like, which are not described herein.

By implementing the embodiments of the present disclosure, by disposing the first insulation layer having a greater density than the second insulation layer between the second insulation layer and the conductive layer, metal ions in the conductive layer can be effectively prevented from diffusing to the color resist layer connected to the second insulation layer, thereby effectively preventing electric leakage.

Further, the method further includes: forming an adhesion layer between the substrate and the conductive layer, the adhesion layer being a molybdenum alloy. The molybdenum alloy includes, but not limited to, any one or a mixture of two or more of MoNb, MoW, MoTi and MoZr. In a specific implementation, the adhesion layer may be formed on the substrate firstly, and then the conductive layer may be formed on the adhesion layer. For example, a substrate is firstly provided, and the substrate is cleaned by deionized water. Then, the adhesion layer is formed on the substrate by a sputtering process using a molybdenum alloy as a sputtering source; and a copper film is formed on the adhesion layer by sputtering, and the copper film is patterned into the conductive layer by processes such as exposure, development, etching, etc.

By implementing the embodiments of the present disclosure, the adhesion between the conductive layer and the substrate can be enhanced by the adhesion layer, which is advantageous for enhancing the stability of the overall structure. Meanwhile, the adhesion layer can also prevent metal ions in the conductive layer from diffusing into the substrate, thereby enhancing the reliability of the product.

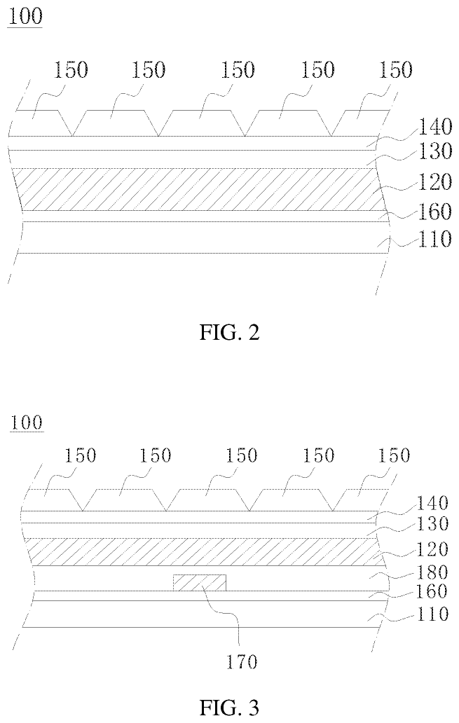

Referring to FIG. 2, which is a schematic view of a conductive layer insulation structure 100 in an embodiment of the present disclosure. The conductive layer insulation structure 100 is applied to a display panel. The display panel includes a substrate 110, a plurality of switching elements, a plurality of data lines, and a plurality of scanning lines. The switching element includes at least a source. A color resist layer 150 is disposed on the substrate, and the data lines and the sources of the switching elements are formed over the substrate 110 to cooperatively serve as a conductive layer 120. The conductive layer insulation structure 100 includes a first insulation layer 130 and a second insulation layer 140.

In a specific implementation, the display panel includes an array substrate, where the array substrate includes the substrate 110, a plurality of switching elements, a plurality of data lines, and a plurality of scanning lines, and the substrate 110 may be formed by a substrate such as a glass substrate, a plastic substrate or the like. The array substrate can be applied to display panels of various display devices. For example, the display panel may be a liquid crystal display panel in a thin film transistor-liquid crystal display (TFT-LCD). Specifically, the array substrate may be a thin film transistor array substrate. The switching element may be a thin film transistor. The switching element may include a source, a gate, a drain, an active layer, etc.

In a specific embodiment, the conductive layer 120 may be a copper metal conductive layer or a copper alloy conductive layer. If the conductive layer 120 is a copper metal conductive layer 120, the formation of the conductive layer 120 can be achieved by depositing a metal copper film on the substrate 110 by sputtering using a pure copper target. The copper film is patterned into the conductive layer 120 by processes such as exposure, development, etching, etc.

If the array substrate is a thin film transistor array substrate, the data lines and the sources of the switching elements are electrically coupled and formed on the substrate 110 to cooperatively serve as the conductive layer 120, referring to FIG. 3 for details, and the scanning lines 170 for being connected to the gate may also be formed between the conductive layer 120 and the substrate 110. A gate insulation layer 180 may be formed between the conductive layer 120 and the scanning lines 170, the gate insulation layer 180 completely covers the scanning lines 170, and the gate insulation layer 180 is used for insulating and separating the conductive layer 120 from the scanning lines 170.

The first insulation layer 130 covers the conductive layer 120.

In a specific embodiment, the method of forming the first insulation layer 130 may include, but not limited to, direct-current vacuum magnetron sputtering, radio-frequency vacuum magnetron sputtering and reactive sputtering.

The first insulation layer 130 may be silicon nitride or silicon oxide. The thickness of the first insulation layer 130 may be 100 angstroms to 300 angstroms, for example, the thickness of the first insulation layer may be 100 angstroms, 200 angstroms, 300 angstroms, or the like.

The second insulation layer 140 covers the first insulation layer 130, and a surface of the second insulation layer 140 away from the first insulation layer 130 is connected to the color resist layer 150.

In a specific implementation, the method of forming the second insulation layer 140 includes, but not limited to, direct-current vacuum magnetron sputtering, radio-frequency vacuum magnetron sputtering and reactive sputtering. The forming speed of the first insulation layer 130 is less than the forming speed of the second insulation layer 140. The density of the first insulation layer 130 is greater than the density of the second insulation layer 140. The second insulation layer 140 may be silicon nitride or silicon oxide.

A surface of the second insulation layer 140 away from the first insulation layer 130 is connected to the color resist layer 150, and the surface connected to the color resist layer 150 may be the upper or side surface of the second insulation layer 140. The color resist layer 150 includes a plurality of color resist blocks disposed in a same layer, and the color resist blocks include a red color resist, a green color resist and a blue color resist. The color resist blocks in the color resist layer 150 may be arranged in an array. For example, the color resist blocks of each row are alternately arranged in the order of the red color resist block, the green color resist block and the blue color resist block.

Specifically, the density of the first insulation layer 130 is greater than the density of the second insulation layer 140. The forming speed of the first insulation layer 130 is less than the forming speed of the second insulation layer 140. The first insulation layer 130 may be silicon oxide.

Specifically, the ratio of the thickness of the first insulation layer 130 to the thickness of the second insulation layer 140 may be 1:10. For example, the thickness of the first insulation layer 130 may be 150 angstroms; and correspondingly, the thickness of the second insulation layer 140 may be 1500 angstroms. Alternatively, the thickness of the first insulation layer 130 may be 200 angstroms; and correspondingly, the thickness of the second insulation layer 140 may be 2000 angstroms. Alternatively, the thickness of the first insulation layer 130 may be 250 angstroms; and correspondingly, the thickness of the second insulation layer 140 may be 2500 angstroms.

The above layers may also be formed in other manners, such as chemical vapor deposition, physical deposition or the like, which are not described herein.

By implementing the embodiments of the present disclosure, by disposing the first insulation layer 130 having a greater density than the second insulation layer 140 between the second insulation layer 140 and the conductive layer 120, metal ions in the conductive layer 120 can be effectively prevented from diffusing to the color resist layer 150 connected to the second insulation layer 140, thereby effectively preventing electric leakage.

Further, the method further includes: forming an adhesion layer 160 between the substrate 110 and the conductive layer 120, the adhesion layer 160 being a molybdenum alloy. The molybdenum alloy includes, but not limited to, any one or a mixture of two or more of MoNb, MoW, MoTi and MoZr. In a specific implementation, the adhesion layer 160 may be formed on the substrate 110 firstly, and then the conductive layer 120 may be formed on the adhesion layer 160. For example, a substrate 110 is firstly provided, and the substrate 110 is cleaned by deionized water. Then, the adhesion layer 160 is formed on the substrate 110 by a sputtering process using a molybdenum alloy as a sputtering source; and a copper film is formed on the adhesion layer 160 by sputtering, and the copper film is patterned into the conductive layer 120 by processes such as exposure, development, etching, etc.

By implementing the embodiments of the present disclosure, the adhesion between the conductive layer 120 and the substrate 110 can be enhanced by the adhesion layer 160, which is advantageous for enhancing the stability of the overall structure. Meanwhile, the adhesion layer 160 can also prevent metal ions in the conductive layer 120 from diffusing into the substrate 110, thereby enhancing the reliability of the product.

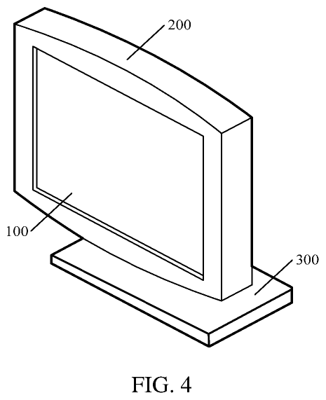

Referring to FIG. 4, which is a schematic view of a display device in an embodiment of the present disclosure. The display device 200 includes a housing 210 and a display panel 220. The display panel 220 includes a substrate, a plurality of pixel units, a plurality of switching elements, a conductive layer insulation structure, a plurality of data lines, and a plurality of scanning lines. The switching element includes at least a source, and the data lines and the sources are formed over the substrate to cooperatively serve as a conductive layer. A color resist layer is disposed on the substrate. The plurality of pixel units and the plurality of switching elements are disposed in areas surrounded by the plurality of data lines and the plurality of scanning lines orthogonally intersected. One pixel unit and one switching element may be disposed in each of the areas surrounded by the data lines and the scanning lines orthogonally intersected. The conductive layer insulation structure is the conductive layer insulation structure 100 in the foregoing embodiment. For a detailed description of the conductive layer insulation structure 100, refer to the foregoing embodiment, and details are not described herein again.

In an embodiment, there are a plurality of the conductive insulation structures, and the plurality of conductive insulation structures cover the plurality of data lines and the plurality of sources of the plurality of switching elements in a one-to-one correspondence.

In another embodiment, there is one conductive insulation structure, and the conductive insulation structure integrally covers the plurality of data lines and the plurality of sources of the plurality of switching elements. The display panel 220 includes, but not limited to, a liquid crystal display (LCD) panel, an organic light-emitting diode (OLED) display panel, a field emission display (FED) panel, a plasma display panel (PDP) and a curved panel. The liquid crystal panel includes a thin film transistor-liquid crystal display (TFT-LCD) panel, a TN (twisted nematic+film) panel, a VA (vertical alignment) panel, an IPS (in plane switching) panel, a COA (color filter on array) panel, etc.

Technical features in the foregoing embodiments may be combined randomly. For the brevity of description, not all possible combinations of various technical features in the foregoing embodiments are described. However, as long as combinations of these technical features do not contradict each other, it should be considered that the combinations all fall within the scope of this specification.

The foregoing embodiments only show several implementations of the present disclosure and are described in detail, but they should not be construed as a limit to the patent scope of the present disclosure. It should be noted that, a person of ordinary skill in the art may make various changes and improvements without departing from the ideas of the present disclosure, which shall all fall within the protection scope of the present disclosure. Therefore, the protection scope of the patent of the present disclosure shall be subject to the appended claims.

1. A conductive layer insulation method, applied to a display panel, wherein the display panel comprises at least a substrate, a plurality of switching elements, a plurality of data lines, and a plurality of scanning lines, a color resist layer is disposed on the substrate, the switching element comprises at least a source, the method comprises:
forming a conductive layer over the substrate, the conductive layer comprising the data line and the source of the switching element;
forming a first insulation layer to cover the conductive layer; and
forming a second insulation layer to cover the first insulation layer, a surface of the second insulation layer away from the first insulation layer being connected to the color resist layer,
wherein a density of the first insulation layer is greater than a density of the second insulation layer.

2. The method according to claim 1, wherein a thickness of the first insulation layer is 100 angstroms to 300 angstroms.

3. The method according to claim 1, wherein a forming speed of the first insulation layer is less than a forming speed of the second insulation layer.

4. The method according to claim 1, wherein a ratio of a thickness of the first insulation layer to a thickness of the second insulation layer is 1:10.

5. The method according to claim 1, wherein a material of the first insulation layer and/or the second insulation layer comprises at least one of silicon nitride and silicon oxide.

6. (canceled)

7. The method according to claim 1, wherein the method further comprises:
forming an adhesion layer between the substrate and the conductive layer, the adhesion layer being a molybdenum alloy.

8. A conductive layer insulation structure, applied to a display panel, wherein the display panel comprises at least a substrate, a plurality of switching elements, a plurality of data lines, and a plurality of scanning lines, a color resist layer is disposed on the substrate, the switching element comprises at least a source, and the data line and the source of the switching element are formed over the substrate to cooperatively serve as a conductive layer, the conductive layer insulation structure comprises:
a first insulation layer, covering the conductive layer; and
a second insulation layer, covering the first insulation layer, a surface of the second insulation layer away from the first insulation layer being connected to the color resist layer,
wherein a density of the first insulation layer is greater than a density of the second insulation layer.

9. The conductive layer insulation structure according to claim 8, wherein a thickness of the first insulation layer is 100 angstroms to 300 angstroms.

10. The conductive layer insulation structure according to claim 8, wherein a ratio of a thickness of the first insulation layer to a thickness of the second insulation layer is 1:10.

11. The conductive layer insulation structure according to claim 8, wherein a material of the first insulation layer or the second insulation layer comprises at least one of silicon nitride and silicon oxide.

12. The conductive layer insulation structure according to claim 8, wherein the color resist layer comprises a plurality of color resist blocks disposed in the same layer, the plurality of color resist blocks comprise a red color resist, a green color resist, and a blue color resist.

13. The conductive layer insulation structure according to claim 8, wherein the scanning line is further formed between the substrate and the conductive layer, a gate insulation layer is formed between the conductive layer and the scanning line, and the gate insulation layer completely covers the scanning line.

14. The conductive layer insulation structure according to claim 8, wherein the conductive layer insulation structure further comprises an adhesion layer, the adhesion layer is disposed between the conductive layer and the substrate, and the adhesion layer is a molybdenum alloy.

15. A display device, the display device comprising a housing and a display panel, wherein the display panel comprises:
a substrate;
a pixel unit;
a switching element;
a conductive layer insulation structure; and
a plurality of data lines and a plurality of scanning lines,
wherein a color resist layer is disposed on the substrate; the switching element comprises at least a source, the data line and the source are formed over the substrate to cooperatively serve as a conductive layer; the pixel unit and the switching element are disposed in areas surrounded by the plurality of data lines and the plurality of scanning lines orthogonally intersected;
wherein the conductive layer insulation structure comprises:
a first insulation layer, covering the conductive layer; and
a second insulation layer, covering the first insulation layer, a surface of the second insulation layer away from the first insulation layer being connected to the color resist layer,
wherein a density of the first insulation layer is greater than a density of the second insulation layer.

16. The display device according to claim 15, wherein a thickness of the first insulation layer is 100 angstroms to 300 angstroms.

17. The display device according to claim 15, wherein a ratio of a thickness of the first insulation layer to a thickness of the second insulation layer is 1:10.

18. The display device according to claim 15, wherein there are a plurality of the pixel units and the switching elements.

19. The display device according to claim 18, wherein there are a plurality of the conductive insulating structures, the plurality of conductive insulating structures cover the plurality of data lines and a plurality of the sources of the plurality of switching elements in a one-to-one correspondence.

20. The display device according to claim 18, wherein there is one conductive insulating structure, the conductive insulating structure integrally covers the plurality of data lines and a plurality of the sources of the plurality of switching elements.
